(19) United States
(12) Patent Application Publication
(10) Pub. No.: US 2026/0143723 A1
(43) Pub. Date: May 21, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Meng-Hsien Lin, Tainan City (TW); Hsing-Chih Lin, Tainan City (TW); Shih-Rong Yang, Hsinchu (TW); Jaio-Wei Wang, Kaohsiung City (TW); Ko Chun Liu, Toufen Township (TW); Jen-Cheng Liu, Hsin-Chu City (TW); Dun-Nian Yaung, Taipei City (TW)

(21) Appl. No.: 18/950,473

(22) Filed: Nov. 18, 2024

(51) Int. Cl. H10D 1/00; H10D 1/68

(52) U.S. Cl. CPC H10D 1/043; H10D 1/714; H10D 1/716

(57) ABSTRACT

Some embodiments relate to an integrated circuit (IC) device that includes a double-sided capacitor structure. The IC device includes dielectric layers disposed over a substrate, and a capacitor structure including capacitor portions. Each capacitor portion includes a first conductive element extending through the dielectric layers, a dielectric element extending through the dielectric layers and aligned along the first conductive element, and a second conductive element extending through the dielectric layers and aligned along the dielectric element. At least one of the dielectric layers includes a first dielectric layer that laterally extends between first neighboring pairs of the capacitor portions, where capacitor portions in each of the first neighboring pairs are separated by less than a first length. The first dielectric layer includes sidewalls defining gaps between each of second neighboring pairs of the capacitor portions, where lengths of the gaps are greater than or equal to the first length.

### BACKGROUND

One area of focus in integrated circuit (IC) technology has been the improvement (e.g., in terms of density, footprint, and so on) of capacitors employed within an IC device. One advancement in this area is the three-dimensional (3D) metal-insulator-metal (MIM) capacitor, which implements a capacitor that possesses a high-level of conductor surface area relative to the volume such a capacitor consumes within the IC device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic side view of some embodiments of a single-sided metal-insulator-metal (MIM) capacitor structure during fabrication, according to the present disclosure.

FIG. 1B illustrates a schematic side view of some embodiments of a double-sided MIM capacitor structure during fabrication, according to the present disclosure.

FIG. 2A illustrates a schematic plan view of some embodiments of a mechanically stable double-sided three-dimensional (3D)-MIM capacitor structure during fabrication, according to the present disclosure.

FIGS. 2B, 2C, and 2D illustrate a plan view, an orthogonal side view, and a diagonal side view, respectively, of a mechanically stable double-sided 3D-MIM capacitor structure, according to the present disclosure.

FIGS. 3 through 9, FIGS. 10A and 10B, FIGS. 11A and 11B, FIGS. 12A, 12B, and 12C, FIGS. 13A and 13B, FIGS. 14A and 14B, and FIGS. 15A and 15B illustrate various side views of some embodiments of an IC device including a mechanically stable double-sided 3D-MIM capacitor structure at various stages of manufacture, according to the present disclosure.

FIG. 16, FIGS. 17A and 17B, and FIGS. 18A and 18B illustrate various side views of additional embodiments of an IC device including a mechanically stable double-sided 3D-MIM capacitor structure at various stages of manufacture, according to the present disclosure.

FIG. 19 illustrates a methodology of forming an IC device including a mechanically stable double-sided 3D-MIM capacitor structure, according to some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

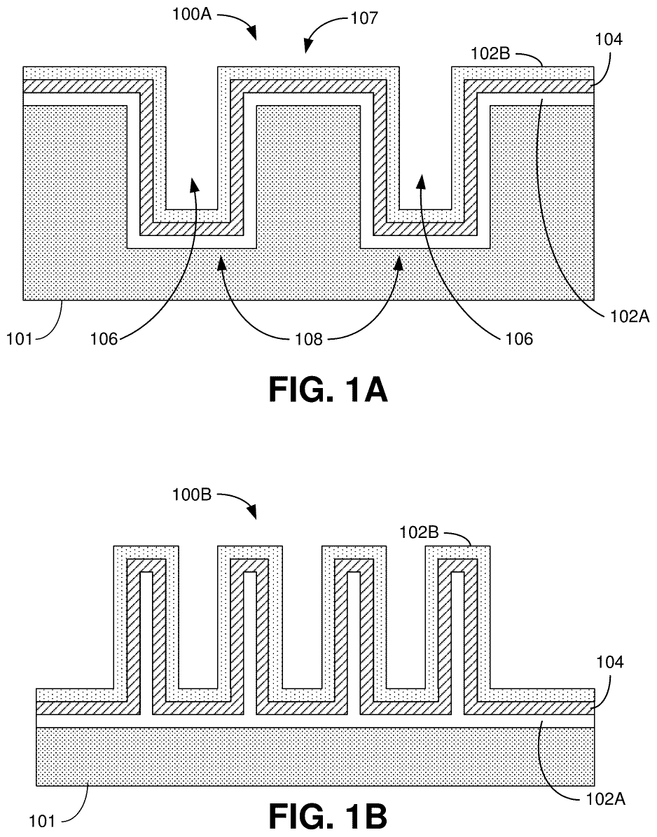

FIG. 1A illustrates a schematic side view of some embodiments of a single-sided metal-insulator-metal (MIM) capacitor structure 100A during fabrication, according to the present disclosure. As shown, a plurality of trenches 106 may be disposed in a base structure 101 (e.g., a dielectric layer, a substrate, or the like). Trenches 106, along with a upper surface of a layer or structure within the IC device, may carry a first conductive element 102A, a dielectric (e.g., insulating) element 104, and a second conductive element 102B that may serve as the metal, insulator, and metal layers, respectively, of MIM capacitor structure 100A. Further, MIM capacitor structure 100A, using elements 102A, 104, and 102B, may include a horizontal body 107 and a plurality of columns 108 extending downward from horizontal body 107. In such an arrangement, all portions of MIM capacitor structure 100A tend to be stable from a mechanical perspective because each portion of MIM capacitor structure 100A is fully supported when formed during IC fabrication.

FIG. 1B illustrates a schematic side view of some embodiments of a double-sided MIM capacitor structure 100B during fabrication, according to the present disclosure. In this configuration, first conductive element 102A may form a plurality of upward-directed segments over which insulating element 104 and second conductive element 102B may be disposed to form MIM capacitor structure 100B. In this arrangement, the upward-directed segments may be narrower and positioned closer together than trenches 106 of MIM capacitor structure 100A, thus potentially providing a greater amount of area for first conductive element 102A, dielectric element 104, and second conductive element 102B, resulting in a higher potential capacitance value.

However, in this particular configuration, providing mechanical support for the upward-directed segments (e.g., portions of first conductive element 102A) during IC device fabrication may be less than optimal, potentially resulting in reduced device yields and increased device fabrication costs.

To address these issues, the present disclosure provides some embodiments of an IC device and associated method of fabrication directed to a mechanically stable double-sided MIM capacitor structure. In some embodiments, the IC device may include a plurality of dielectric layers disposed over a substrate, and a capacitor structure including a plurality of capacitor portions. Each capacitor portion may include a first conductive element extending through the dielectric layers, a dielectric element extending through the dielectric layers and aligned along the first conductive element, and a second conductive element extending through the dielectric layers and aligned along the dielectric element. At least one of the dielectric layers may laterally span or bridge a linear distance between each pair of neighboring capacitor portions that are separated by less than some length. Oppositely, the at least one of the dielectric layers may not laterally span or bridge a linear distance between each pair of neighboring capacitor portions that are separated by greater than or equal to the length.

Accordingly, use of some embodiments of the method may provide a physical feature, such as the at least one of the dielectric layers described above, that provides mechanical stability to the capacitor structure, particularly during fabrication of the IC device, by spanning linear distances between various neighboring pairs of the capacitor portions. Further, in some embodiments, as a result of the at least one of the dielectric layers not spanning between other neighboring pairs of the capacitor portions, lower layers of the IC device below the at least one of the dielectric layers may be accessed to provide material for additional one or more capacitor portions alongside the first capacitor portions to produce a double-sided MIM capacitor structure.

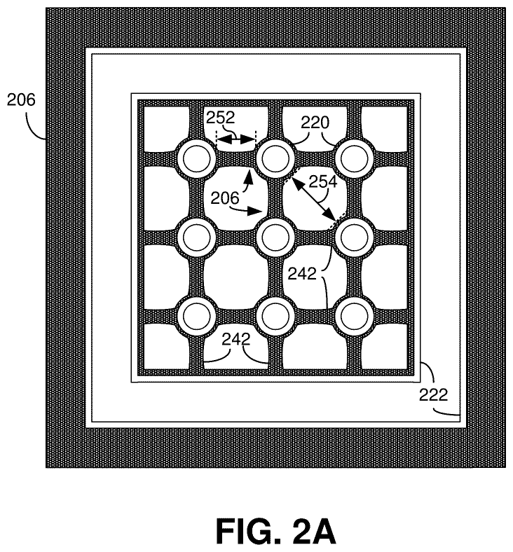

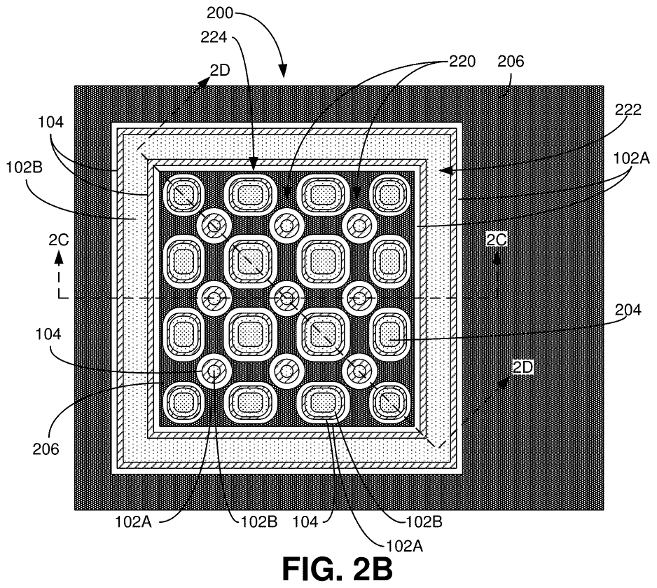

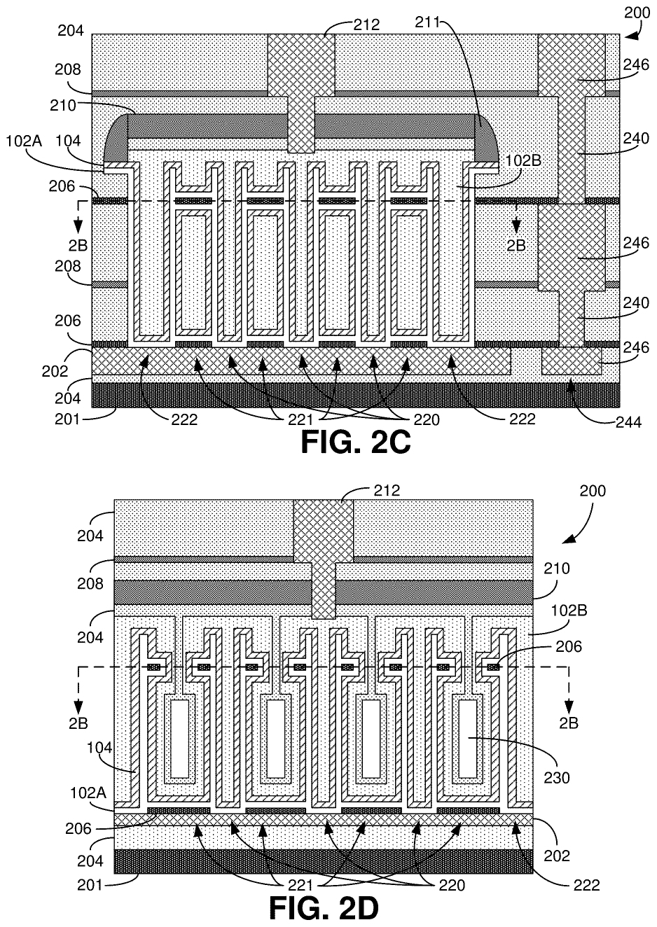

FIG. 2A illustrates a plan view of a mechanically stable double-sided three-dimensional (3D)-MIM capacitor structure during fabrication, according to the present disclosure. In some embodiments, first conductive element 102A, in conjunction with a first (bottom) electrode 202, as discussed above in connection with FIG. 1B, may be arranged as a plurality of first capacitor portions 220 that may include vertically-oriented portions (e.g., cylinders). As also shown in FIG. 2A, a portion of first conductive element 102A may form part of a protective ring 222 that may provide structural and/or electrical isolation for the resulting 3D-MIM capacitor structure.

To provide stability to first conductive element 102A during subsequent processing, such as the addition of insulating element 104 and second conductive element 102B, structural elements 242 may laterally join or span adjacent first capacitor portions 220 to each other and/or laterally join or span one or more first capacitor portions 220 to a portion of protective ring 222. In some embodiments, structural elements 242 may be formed from a structural dielectric layer 206, such as an etch stop layer. More specifically, in some embodiments, structural dielectric layer 206 may laterally join or span neighboring first capacitor portions 220 that are separated by less than a particular length (e.g., first length 252 less than the particular length). Further, in some embodiments, structural dielectric layer 206 may include sidewalls that define gaps between some neighboring first capacitor portions 220, where lengths of the gaps are greater than or equal to the particular length (e.g., second length 254 greater than or equal to the particular length). Additionally, in some embodiments associated with the plan view of FIG. 2A in which first capacitor portions 220 are arranged as a two-dimensional array, structural dielectric layer 206 may join or span first capacitor portions 220 along rows and columns of the array, while structural dielectric layer 206 may define gaps between first capacitor portions 220 along diagonals of the array.

FIGS. 2B, 2C, and 2D illustrate a plan view, an orthogonal side view, and a diagonal side view, respectively, of a mechanically stable double-sided 3D-MIM capacitor structure 200, according to the present disclosure. As depicted, FIG. 2A is a plan view of capacitor structure 200 at a particular structural dielectric layer 206 that selectively spans distances between pairs of first capacitor portions 220. In some embodiments, each first capacitor portion 220 may include a cylindrical structure that appears circular as shown in the plan view of FIG. 2B. Further, each first capacitor portion 220 may include a first conductive element 102A that is cylindrical in shape; a dielectric (e.g., insulating) element 104 that is cylindrical, and is aligned coaxially and in contact with first conductive element 102A; and a second conductive element 102B that is cylindrical, and is aligned coaxially and in contact with dielectric element 104.

In some embodiments, structural dielectric layer 206, as shown in FIG. 2B, laterally spans a linear distance between neighboring first capacitor portions 220 that are separated by less than some predetermined length (e.g., along the orthogonal cross-section of FIG. 2C), but does not laterally span a linear distance between neighboring first capacitor portions 220 that are separated by greater than or equal to the predetermined length (e.g., along the diagonal cross-section of FIG. 2D).

Further, in some embodiments, as depicted in the plan view of FIG. 2B, first capacitor portions 220 may be arranged as a two-dimensional rectangular array having rows and columns. In the particular case of FIG. 2B, first capacitor portions 220 are arranged in a 3-by-3 array. However, other sizes and configurations of arrays (e.g., 1-by-2, 2-by-1, 2-by-2, 2-by-3, 3-by-2, 4-by-4, and so on) may be employed in other embodiments. Accordingly, neighboring first capacitor portions 220 along rows or columns of the two-dimensional array (e.g., along the cross-section of FIG. 2C) are separated by a relatively short distance (e.g., less than the predetermined length), and thus that distance is spanned by structural dielectric layer 206. Otherwise, neighboring first capacitor portions 220 not aligned along one of the rows or columns of the two-dimensional array (e.g., along a diagonal of the two-dimensional array, such as the cross-section of FIG. 2D) are separated by a relatively long distance (e.g., greater than or equal to the predetermined length).

First capacitor portions 220 are also shown in cross-section in FIGS. 2C and 2D. In some embodiments, first capacitor portions 220 may be laterally separated by one or more second capacitor portions 221 that include a first conductive element 102A, a dielectric element 104, and a second conductive element 102B to facilitate a double-sided 3D-MIM capacitor structure. As discussed in greater detail below, the volume between first capacitor portions 220 in which the one or more second capacitor portions 221 are formed may be accessible during fabrication via one or more openings 224 in structural dielectric layer 206 (e.g., as shown in FIG. 2B).

Further, in some embodiments, as shown to best effect in the plan view of FIG. 2B, first capacitor portions 220 and second capacitor portions 221 may be surrounded laterally by a protective ring 222. In some embodiments, protective ring 222 may include a core of second conductive element 102B, which may be laterally surrounded by dielectric element 104, which in turn may be laterally surrounded by first conductive element 102A (e.g., in a manner similar to that of each first capacitor portion 220). In some embodiments, protective ring 222 provides an electrical barrier between capacitor structure 200 and surrounding electrical components that may be provided in the IC device that includes capacitor structure 200. Further, in some embodiments, during fabrication, protective ring 222 may protect other circuits surrounding the 3D-MIM capacitor structure, such as by constraining solvents within the area of the 3D-MIM capacitor structure.

In some embodiments, as shown in the cross-sections of FIGS. 2C and 2D, a first (bottom) electrode 202 (e.g., including a metal or metal alloy (e.g., copper (Cu), another conductive metal or alloy, or another conductive material) may be disposed over a dielectric layer 204, which, in turn may be disposed over a substrate 201 (e.g., a semiconductor substrate that may include silicon (Si), another semiconductor material, or some combination thereof). First electrode 202, in some embodiments, may be connected directly or indirectly to one or more first capacitor portions 220, second capacitor portions 221, and/or protective ring 222 to another electronic circuit or voltage reference of the IC device.

Further, in some embodiments, first capacitor portions 220, second capacitor portions 221, and/or protective ring 222 may reside within one or more dielectric layers 204, 206, and 208. In some embodiments, each of dielectric layers 204, 206, and 208 may include one or more dielectric materials, including, but not limited to, silicon oxide (SiOₓ) (e.g., silicon oxide (SiO₂)), silicon nitride (SiN), silicon carbide (SiC), carbon doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like. For example, in some embodiments, dielectric layers 204 may include silicon oxide, dielectric layers 206 may include silicon oxynitride (SiON), silicon nitride (SiN), silicon carbide (SiC) (e.g., employed as an etch stop layer), and dielectric layers 208 may include silicon nitride (SiN) (e.g., as an interlayer dielectric). Also, while a particular arrangement and thickness of dielectric layers 204, 206, and 208 is depicted in FIGS. 2C and 2D, other arrangements and thicknesses are possible in other embodiments. As described in greater detail herein, dielectric layer 206 may provide mechanical stability for capacitor structure 200 during fabrication. Additionally or alternatively, in some embodiments, one or more other dielectric layers 204, 206, and 208 may provide such stability.

Regarding first capacitor portions 220 and second capacitor portions 221, first conductive element 102A (e.g., also referred to as a capacitor bottom metal (CBM)) and second conductive element 102B (e.g., also referred to as a capacitor top metal (CTM)) may each include a metal (e.g., copper (Cu) or another metal or metal alloy) or another conductive material (e.g., polycrystalline silicon, silicon oxynitride (SiON), titanium nitride (TiN), tantalum nitride (TaN), and so on). In some embodiments, first conductive element 102A and second conductive element 102B may include the same or different materials. Further, in some embodiments, dielectric element 104 may include an insulator and/or other insulating or dielectric material.

As shown in the cross-sections of FIGS. 2C and 2D, a dielectric cover layer 210 may be disposed over second conductive element 102B and a dielectric layer 204. In addition, a dielectric spacer 211 may be disposed over dielectric element 104 and laterally surround dielectric cover layer 210, dielectric layer 204, and a portion of second conductive element 102B. In some embodiments, dielectric cover layer 210 and dielectric spacer 211 may be made of the same dielectric material, such as silicon nitride, although other dielectric materials may be used in other embodiments.

In some embodiments, a second electrode 212 may contact second conductive elements 102B. Second electrode 212 may include a conductive material, such as copper (Cu), a copper alloy, another metal, or another conductive material. Also, in some embodiments, second electrode 212 may have a wider upper portion and a narrower lower portion. The narrower lower portion may extend through dielectric cover layer 210 and dielectric layer 204 to make contact with second conductive elements 102B.

First electrode 202 and second electrode 212 may serve as the two electrical connections for MIM capacitor structure 200 employed in an IC device. In some embodiments, MIM capacitor structure 200 may serve as a component in a digital or analog circuit, such as a bypass or decoupling capacitor (e.g., for direct current (DC) voltages, such as power supply voltages).

As shown in the cross-section of FIG. 2C, in some embodiments, one or more conductive interconnect structures 244 may be disposed in dielectric layers 204, 206, and 208 near the first and second conductive elements 102A and 102B. The one or more conductive interconnect structures 244 may include conductive wires 246 vertically stacked with conductive vias 240. Conductive wires 246 and conductive vias 240 may, for example, include copper (Cu), aluminum (Al), titanium nitride (TiN), tantalum nitride (TaN), ruthenium (Ru), some other conductive material, or any combination of the foregoing.

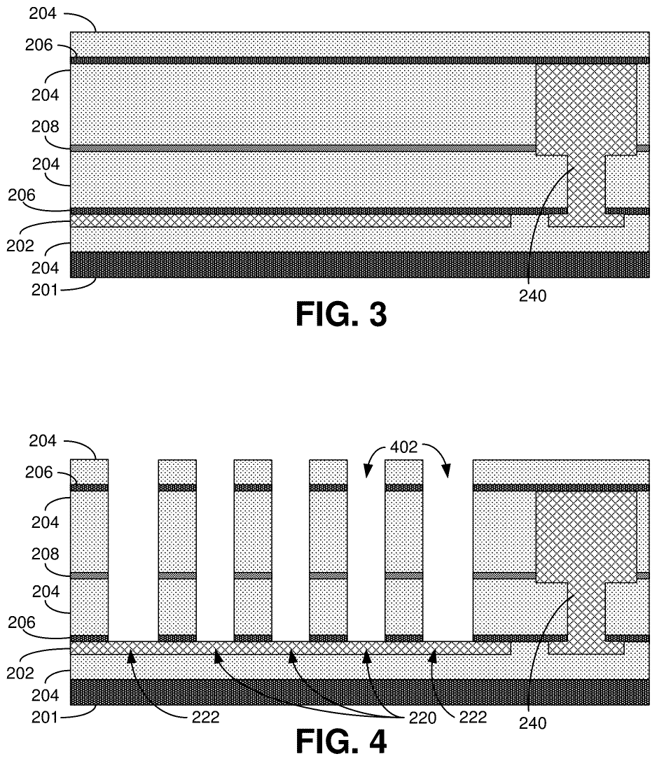

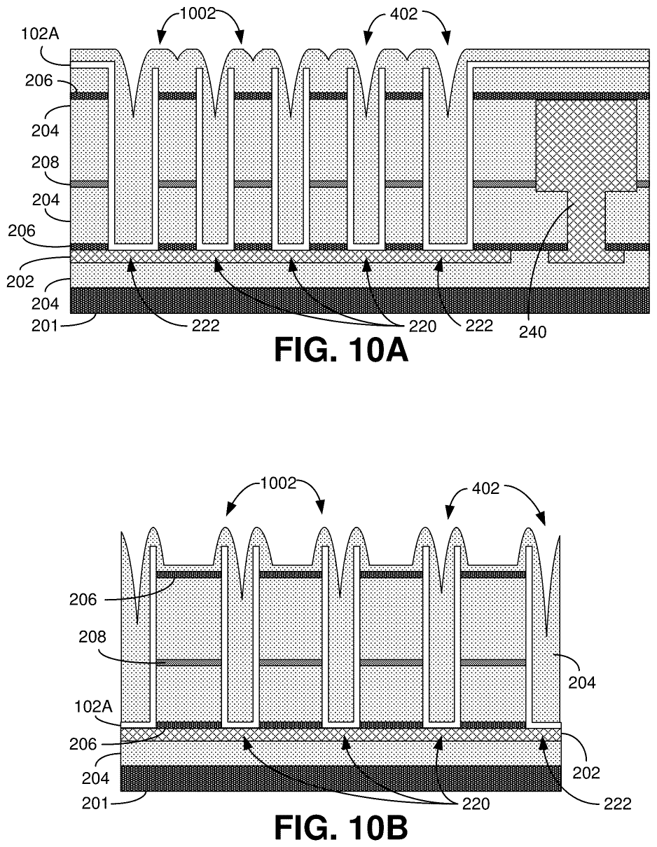

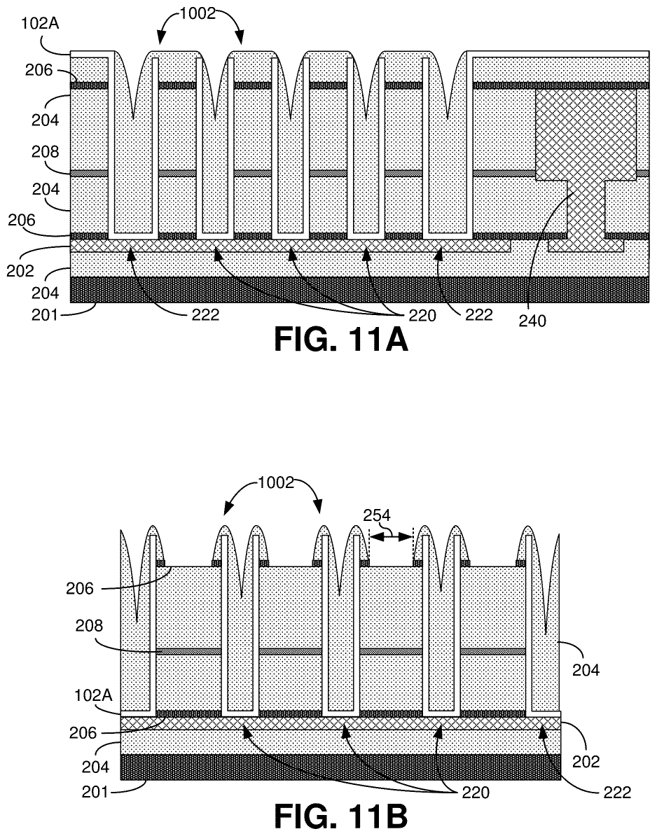

FIGS. 3 through 9, FIGS. 10A and 10B, FIGS. 11A and 11B, FIGS. 12A, 12B, and 12C, FIGS. 13A and 13B, FIGS. 14A and 14B, and FIGS. 15A and 15B illustrate various side views of some embodiments of an IC device including a mechanically stable double-sided 3D-MIM capacitor structure (e.g., capacitor structure 200) at various stages of manufacture, according to the present disclosure. More specifically, FIGS. 3 through 9 and FIGS. 10A through 15A are orthogonal cross-sectional views at the same cross-sectional line as FIG. 2C. FIGS. 10B through 15B are diagonal cross-sectional views at the same cross-sectional line as FIG. 2D and are views of the same stage of manufacture as FIGS. 10A through 15A, respectively. Although FIGS. 3 through 9, FIGS. 10A and 10B, FIGS. 11A and 11B, FIGS. 12A, 12B, and 12C, FIGS. 13A and 13B, FIGS. 14A and 14B, and FIGS. 15A and 15B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 3 illustrates a first electrode 202 over which a plurality of dielectric layers 204, 206, and 208 are disposed. In some embodiments, a substrate 201 (e.g., a silicon (Si) substrate) may support a first dielectric layer 204, over which first electrode 202 may be formed, followed by the forming of successive additional dielectric layers 204, 206, and 208. As illustrated in FIG. 3, relatively thin structures of dielectric layers 206 and 208 may be formed in an alternating manner between thicker structures of dielectric layer 204, although many other structures and orders of formation may be employed using dielectric layers 204, 206, and/or 208. As indicated above, in some embodiments, each of dielectric layers 204, 206, and 208 may include one or more dielectric materials, including, but not limited to, silicon oxide (SiOₓ), such as silicon dioxide (SiO₂), silicon nitride (SiN), and silicon carbide (SiC). For example, dielectric layers 204 may include silicon oxide (SiOₓ), dielectric layers 206 may include silicon carbide (SiC), and dielectric layers 208 may include silicon nitride (SiN), although other materials and combinations are also possible. Further, in some embodiments, the upper dielectric layer 206 illustrated in FIG. 3 may be employed as structural dielectric layer 206 of FIGS. 2B, 2C, and 2D.

Additionally, in some embodiments, one or more conductive vias 240 and associated metal layers may be disposed in dielectric layers 204, 206, and 208 near (e.g., surrounding) the 3D-MIM capacitor structure to be fabricated, as depicted in subsequent figures.

FIG. 4 illustrates the removal (e.g., by photolithography and etching) of a plurality of trenches 402 that will determine the location of each first capacitor portion 220 and protective ring 222. In some embodiments, each trench 402 extends from an upper surface of the uppermost dielectric layer 204 to an upper surface of first electrode 202.

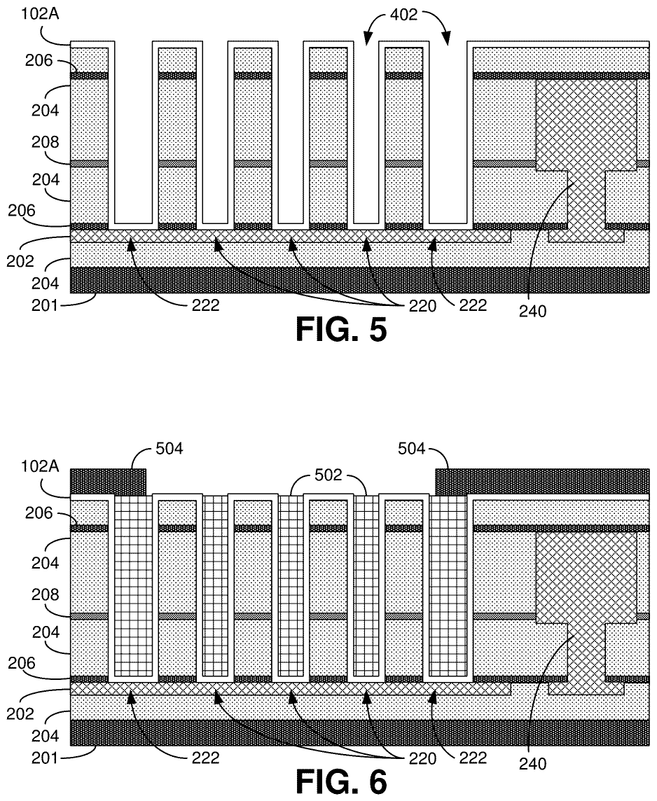

FIG. 5 illustrates the forming (e.g., conformal deposition) of first conductive element 102A internal and external to (e.g., between) trenches 402. As indicated above, first conductive element 102A may include a metal (e.g., copper (Cu)), metal alloy, and/or another conductive material (e.g., polycrystalline silicon, tantalum nitride (TaN), and so on).

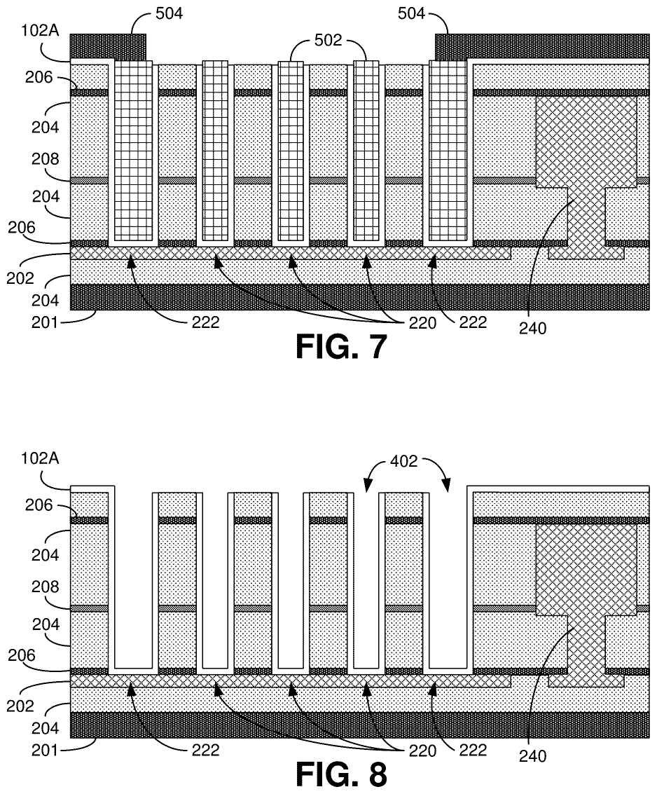

FIG. 6 illustrates the forming (e.g., deposition) of protective plugs 502 that fill trenches 402, as well as the forming of photoresist material 504 that may protect portions of first conductive element 102A that do not lie between adjacent trenches 402. In some embodiments, protective plugs 502 may be formed from a fluid organic-type material. Together, protective plugs 502 and photoresist material 504 may facilitate the selective removal (e.g., etching) of portions of first conductive element 102A lying between adjacent trenches 402, as illustrated in FIG. 7, to form individual first conductive elements 102A. Thereafter, FIG. 8 illustrates the removal (e.g., dissolution) of protective plugs 502 and photoresist material 504.

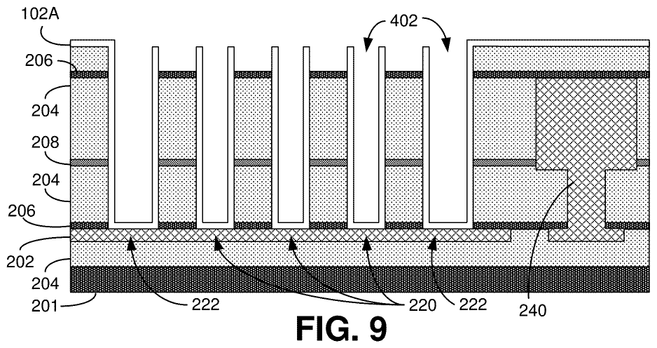

FIG. 9 illustrates the removal (e.g., wet removal or dissolution using a solvent, such as hydrofluoric (HF) acid) of an upper dielectric layer 204 (e.g., silicon oxide (SiOx), such as silicon dioxide (SiO2), or another soluble dielectric material), extending downward to the upper instance of structural dielectric layer 206. In some embodiments, structural dielectric layer 206 may include silicon carbide (SiC) or another dielectric material that is more resistant to dissolution in a particular solvent than dielectric layer 204.

FIGS. 10A and 10B illustrate orthogonal and diagonal cross-sectional views, respectively, of the forming (e.g., deposition) of dielectric spacer structures 1002 over the exposed conductive surfaces (e.g., surfaces of first conductive elements 102A). In some embodiments, the deposited dielectric spacer structures 1002 may form a dielectric layer 204 with an uneven upper surface that may roughly follow at least some of the contours of the underlying first conductive elements 102A and portions of structural dielectric layer 206.

FIGS. 11A and 11B illustrate orthogonal and diagonal cross-sectional views, respectively, of the removal (e.g., broad or “blanket” etching) of dielectric material from dielectric spacer structures 1002. In some embodiments, a sufficient amount of the dielectric material may be removed from dielectric spacer structures 1002 to remove portions of first (structural) dielectric layer 206 between neighboring ones of the plurality of trenches 402 (e.g., associated with first capacitor portions 220) that are separated by at least a first linear distance (e.g., a length 254 between neighboring ones of the plurality of trenches 402 along a diagonal of the associated two-dimensional array in the plan view), as shown in FIG. 11B. In some embodiments, dielectric spacer structures 1002 may be thinner between trenches 402 positioned along the diagonal directions. Further, in such embodiments, such removal may leave intact remaining portions of first dielectric layer 206 (e.g., between neighboring ones of the plurality of trenches 402 along an orthogonal line of the associated two-dimensional array in the plan view), as shown in FIG. 11A. Leaving intact such remaining portions of first dielectric layer 206 may provide mechanical stability for further fabrication stages.

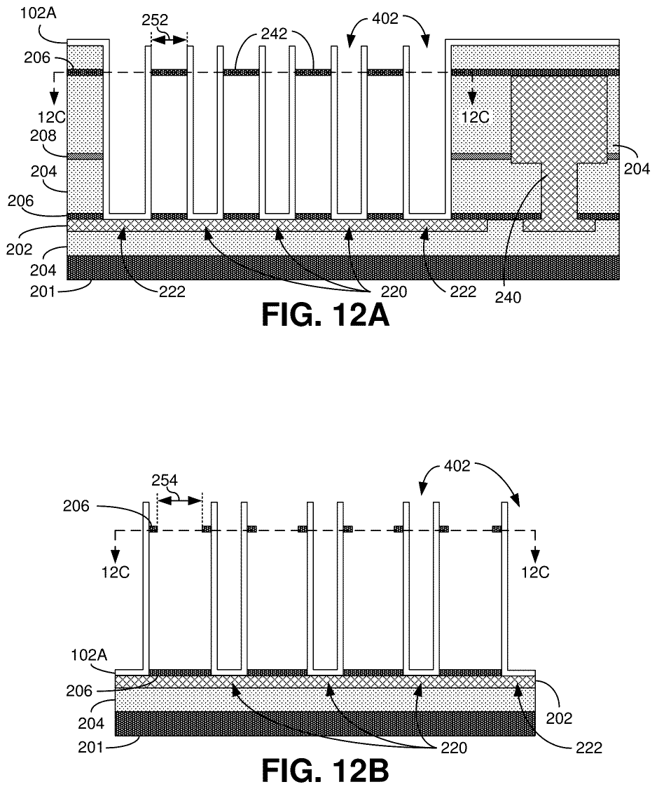

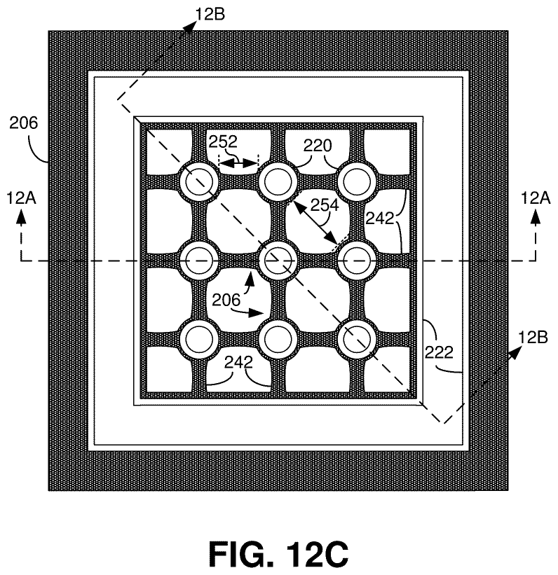

For example, FIGS. 12A, 12B, and 12C illustrate orthogonal cross-sectional, diagonal cross-sectional, and plan views, respectively, of the removal (e.g., wet dip removal or dissolution) of additional ones of the plurality of dielectric layers (e.g., by way of the at least one removed portion of first dielectric layer 206). For example, all exposed dielectric layers other than first dielectric layer 206 (e.g., dielectric layers 204 and 208) may be removed, including those shown in FIG. 12A, as access is facilitated by the openings of first dielectric layer 206 depicted in FIG. 12B.

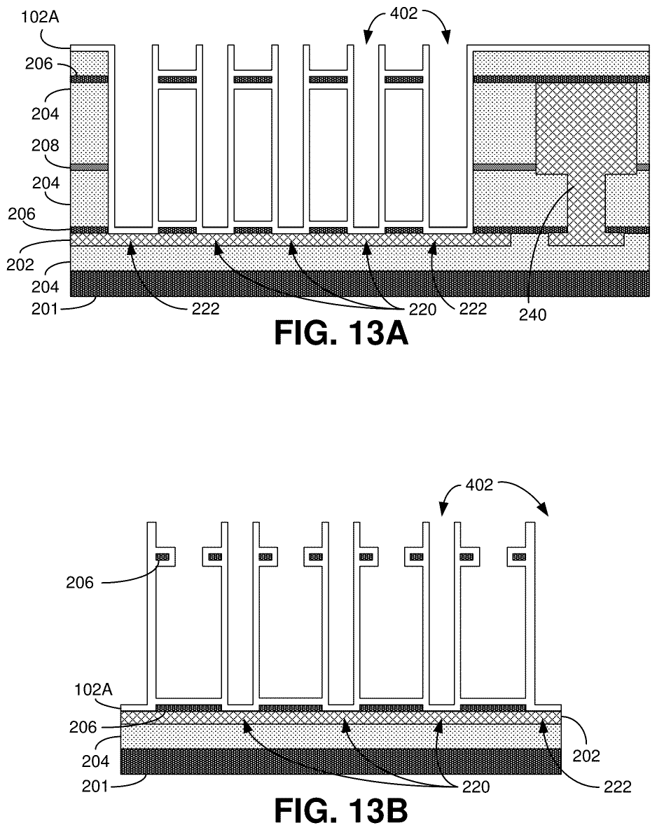

At this stage of fabrication, additional material layers may be formed to complete fabrication of first capacitor portions 220, second capacitor portions 221, and/or protective ring 222. For example, FIGS. 13A and 13B illustrate orthogonal and diagonal cross-sectional views, respectively, of the forming (e.g., conformal deposition) of a first conductive material internal and external to the plurality of trenches 402 (e.g., to complete first conductive elements 102A of first capacitor portions 220 and second capacitor portions 221). In some embodiments, such deposition may facilitate application of the conductive material (e.g., a metal (copper (Cu)), metal alloy, or another conductive material (e.g., polycrystalline silicon, tantalum nitride (TaN), and so on) onto exposed upper and lower dielectric layers 206, as well as the previously existing portions of first conductive element 102A. For example, in some embodiments, the conductive material may be deposited by way of atomic layer deposition (ALD). Such deposition may allow all exposed upper, lower, and lateral surfaces of the dielectric material of dielectric layers 206, and possibly first conductive element 102A, to be covered with the first conductive material.

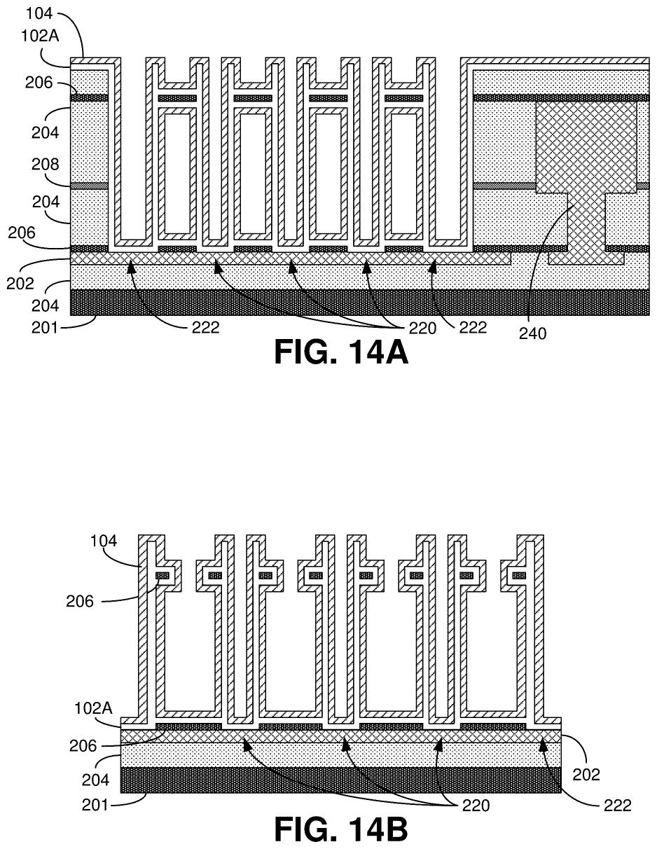

FIGS. 14A and 14B illustrate orthogonal and diagonal cross-sectional views, respectively, of the forming (e.g., conformal deposition) of a dielectric material over the first conductive material (e.g., to form dielectric elements 104 of first capacitor portions 220 and second capacitor portions 221). In some embodiments, the dielectric material may include an insulator and/or other dielectric material.

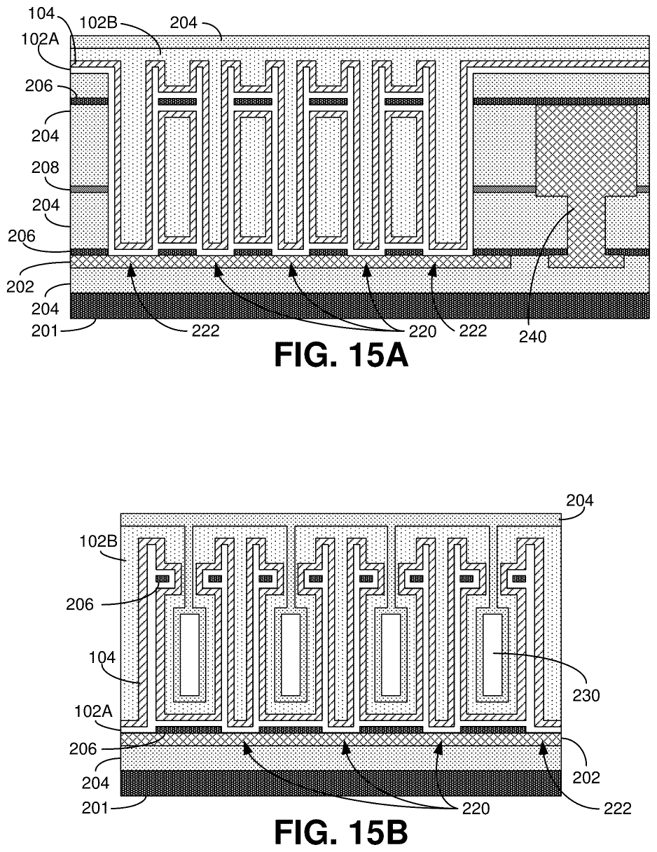

FIGS. 15A and 15B illustrate orthogonal and diagonal cross-sectional views, respectively, of the forming (e.g., deposition or filling) of a second conductive material on the dielectric material (e.g., to form second conductive elements 102B of first capacitor portions 220 and second capacitor portions 221). In some embodiments, a sufficient amount of the second conductive material may cover all of dielectric elements 104. Also shown in FIGS. 15A and 15B, in some embodiments, one or more voids 230 may form within the second conductive material 102B of the one or more second capacitor portions 221 between first capacitor portions 220 or protective ring 222.

Thereafter, dielectric cover layer 210 and dielectric spacer 211 may be formed over dielectric element 104 to laterally surround dielectric cover layer 210, dielectric layer 204, and a portion of second conductive element 102B, as discussed above in conjunction with FIGS. 2C and 2D. Further, in some embodiments, second electrode 212 may be formed to extend through dielectric cover layer 210 and dielectric layer 204 to make contact with second conductive element 102B.

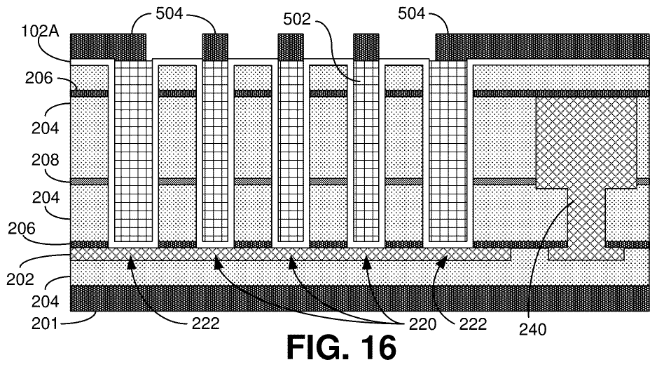

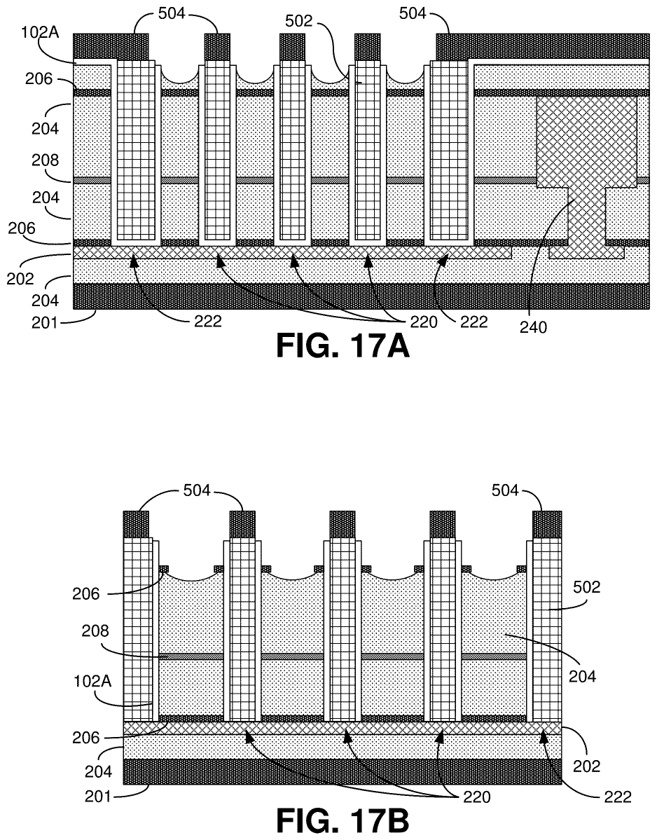

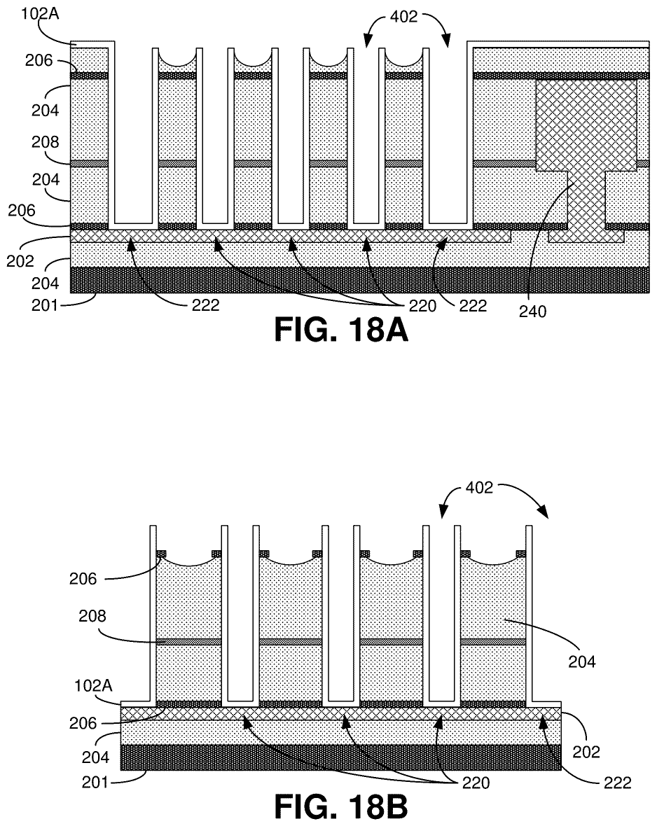

In some embodiments, a partial process that represents an alternative to the stages of fabrication discussed above in relation to FIGS. 6 through 9 and FIGS. 10A, 10B, 11A, and 11B are depicted in FIG. 16, FIGS. 17A and 17B, and FIGS. 18A and 18B. This partial process addresses the stages employed to create the openings in structural dielectric layer 206 after the forming (e.g., conformal deposition) of first conductive elements 102A depicted in FIG. 5.

For example, FIG. 16 illustrates the forming (e.g., deposition) of protective plugs 502 that fill trenches 402, as well as the forming of photoresist material 504 that may protect portions of first conductive element 102A that do not lie between adjacent trenches 402, as well as protect protective plugs 502 in those trenches 402 associated with first capacitor portions 220. Together, protective plugs 502 and photoresist material 504 may facilitate the selective removal (e.g., etching) of portions of first conductive element 102A lying between adjacent trenches 402, as well as some of dielectric layer 204, along rows or columns of the two-dimensional array, as depicted in the cross-sectional view of FIG. 17A. In addition, in some embodiments, along a diagonal of the array, as illustrated in the cross-sectional view of FIG. 17B, underlying structural dielectric layer 206 between trenches 402 may be removed, as is a portion of structural dielectric layer 206 (e.g., due to the farther distance between trenches 402 along the diagonal cross-section). The cross-sectional views of FIGS. 18A and 18B illustrate the subsequent removal (e.g., dissolution) of protective plugs 502 and photoresist material 504.

At this stage, the process may proceed as shown in FIGS. 12A, 12B, and 12C, which illustrate orthogonal cross-sectional, diagonal cross-sectional, and plan views, respectively, of the removal (e.g., wet dip removal or dissolution) of additional ones of the plurality of dielectric layers (e.g., by way of the at least one removed portion of first dielectric layer 206). As described above, all exposed dielectric layers other than first dielectric layer 206 (e.g., dielectric layers 204 and 208) may be removed, including those shown in FIG. 12A, as access may be facilitated by the openings of first dielectric layer 206 depicted in FIG. 12B. Fabrication may then continue as discussed above in conjunction with FIGS. 13A and 13B, FIGS. 14A and 14B, and FIGS. 15A and 15B.

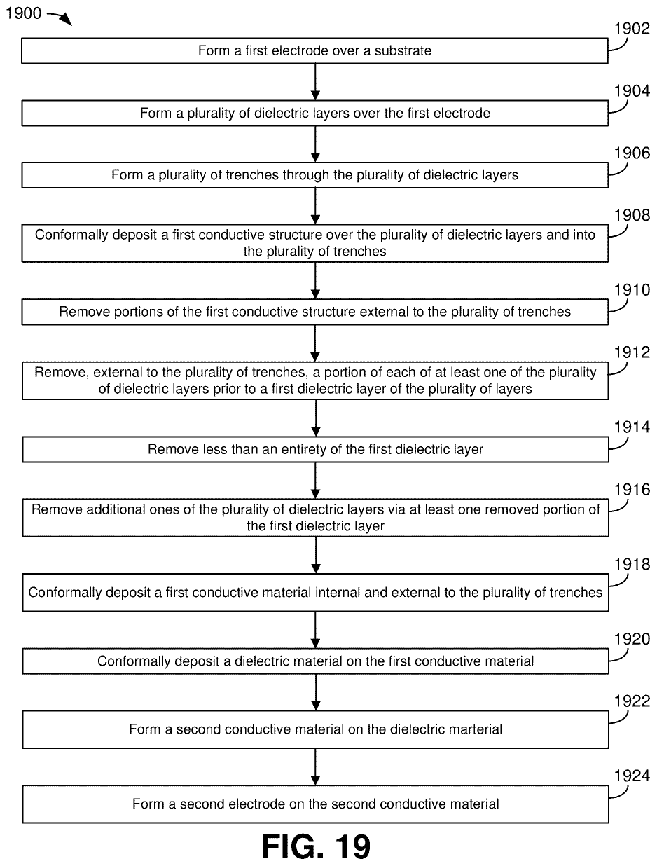

FIG. 19 illustrates a methodology 1900 of forming an IC device including a mechanically stable double-sided MIM capacitor structure (e.g., MIM capacitor structure 200 of FIGS. 2B, 2C, and 2D), in accordance with some embodiments. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 1902, for example, a first electrode (e.g., first electrode 202 of FIGS. 2B, 2C, and 3) may be formed over a substrate (e.g., substrate 201 of FIGS. 2C, 2D, and 3). At Act 1904, a plurality of dielectric layers (e.g., dielectric layers 204, 206, and 208 of FIG. 3) may be formed over the first electrode. FIG. 3 illustrates a cross-sectional view of some embodiments corresponding to Acts 1902 and 1904.

At Act 1906, a plurality of trenches (e.g., trenches 402 of FIG. 4) may be formed through the plurality of dielectric layers. As indicated above, each of the trenches may determine the location of a corresponding first capacitor portion 220. FIG. 4 illustrates a cross-sectional view of some embodiments corresponding to Act 1906.

At Act 1908, a first conductive structure (e.g., first conductive elements 102A of FIG. 5) may be conformally deposited over the plurality of dielectric layers and into the plurality of trenches. FIG. 5 illustrates a cross-sectional view of some embodiments corresponding to Act 1908.

At Act 1910, portions of the first conductive structure external to the plurality of trenches may be removed. At Act 1912, a portion of each of at least one of the plurality of dielectric layers external to the plurality of trenches may be removed prior to a first dielectric layer (e.g., structural dielectric layer 206 of FIGS. 2B, 2C, and 2D) of the plurality of dielectric layers. Further, at Act 1914, less than an entirety of the first dielectric layer may be removed. FIGS. 6 through 9, FIGS. 10A and 10B, and FIGS. 11A and 11B illustrate cross-sectional views of some embodiments corresponding to Acts 1910, 1912, and 1914. Alternatively, FIG. 16, FIGS. 17A and 17B, and FIGS. 18A and 18B illustrate cross-sectional views of some embodiments corresponding to Acts 1910, 1912, and 1914.

At Act 1916, additional ones of the plurality of dielectric layers (e.g., dielectric layers 204 and 208 of FIGS. 11A and 11B) may be removed via at least one removed portion of the first dielectric layer. FIGS. 12A and 12B illustrate cross-sectional views of some embodiments corresponding to Act 1916.

At Act 1918, a first conductive material (e.g., for first conductive element 102A of FIGS. 13A and 13B) may be conformally deposited internal and external to the plurality of trenches. FIGS. 13A and 13B illustrate cross-sectional views of some embodiments corresponding to Act 1918.

At Act 1920, a dielectric material (e.g., dielectric element 104 of FIGS. 14A and 14B) may be conformally deposited on the first conductive material. FIGS. 14A and 14B illustrate cross-sectional views of some embodiments corresponding to Act 1920.

At Act 1922, a second conductive material (e.g., second conductive element 102B of FIGS. 15A and 15B) may be formed on the dielectric material. FIGS. 15A and 15B illustrate cross-sectional views of some embodiments corresponding to Act 1922.

At Act 1924, a second electrode (e.g., second electrode 212 of FIGS. 2C and 2D) may be formed to make contact with the second conductive material. Consequently, in some embodiments, the first and second electrodes may serve as contact points to access the MIM capacitor structure (e.g., MIM capacitor structure 200 of FIGS. 2B, 2C, and 2D). FIGS. 2C and 2D illustrate cross-sectional views of some embodiments corresponding to Act 1924.

Some embodiments relate to an IC device. The IC device includes a plurality of dielectric layers disposed over a substrate, and a capacitor structure including a plurality of capacitor portions. Each of the plurality of capacitor portions includes a first conductive element extending through the dielectric layers, a dielectric element extending through the dielectric layers and aligned along the first conductive element, and a second conductive element extending through the dielectric layers and aligned along the dielectric element. The plurality of dielectric layers includes a first dielectric layer that laterally extends between first neighboring pairs of the plurality of capacitor portions, wherein capacitor portions in the first neighboring pairs of the plurality of capacitor portions are each separated by less than a first length. The first dielectric layer includes sidewalls defining gaps between each of second neighboring pairs of the plurality of capacitor portions, wherein lengths of the gaps are greater than or equal to the first length.

Some embodiments relate to another IC device. The IC device includes a plurality of dielectric layers disposed over a substrate, and a capacitor structure including a plurality of capacitor portions. Each of the plurality of capacitor portions includes a first conductive element extending through the dielectric layers, a dielectric element extending through the dielectric layers and aligned along the first conductive element, and a second conductive element extending through the dielectric layers and aligned along the dielectric element. The plurality of capacitor portions are arranged in a two-dimensional array in a plan view of the IC device. At least one of the dielectric layers bridges each neighboring pair of the plurality of capacitor portions aligned along a row or a column of the two-dimensional array. The at least one of the dielectric layers includes a gap between each other neighboring pair of the plurality of capacitor portions.

Some embodiments relate to a method. The method includes forming a first electrode over a substrate; forming a plurality of dielectric layers over the first electrode; forming a plurality of trenches through the plurality of dielectric layers; conformally depositing a first conductive structure over the plurality of dielectric layers and into the plurality of trenches; removing portions of the first conductive structure external to the plurality of trenches; removing, external to the plurality of trenches, a portion of each of at least one of the plurality of dielectric layers prior to a first dielectric layer of the plurality of dielectric layers; removing less than an entirety of the first dielectric layer; removing additional ones of the plurality of dielectric layers via at least one removed portion of the first dielectric layer; conformally depositing a first conductive material internal and external to the plurality of trenches; conformally depositing a dielectric material on the first conductive material; forming a second conductive material on the dielectric material; and forming a second electrode on the second conductive material.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a substrate;
a plurality of dielectric layers disposed over the substrate;
a capacitor structure comprising a plurality of first capacitor portions, each of the plurality of first capacitor portions comprising:
a first conductive element extending through the plurality of dielectric layers;
a dielectric element extending through the plurality of dielectric layers and aligned along the first conductive element; and
a second conductive element extending through the plurality of dielectric layers and aligned along the dielectric element;
wherein at least one of the plurality of dielectric layers comprises a first dielectric layer that laterally extends between first neighboring pairs of the plurality of first capacitor portions, wherein first capacitor portions in each of the first neighboring pairs of the plurality of first capacitor portions are separated by less than a first length, wherein the first dielectric layer comprises sidewalls defining gaps between each of second neighboring pairs of the plurality of first capacitor portions, wherein lengths of the gaps are greater than or equal to the first length.

2. The IC device of claim 1, wherein:
the plurality of first capacitor portions are arranged in a two-dimensional array in a plan view of the IC device;
each of the first neighboring pairs of the plurality of first capacitor portions is aligned along a row or a column of the two-dimensional array; and
each of the second neighboring pairs of the plurality of first capacitor portions is aligned along a diagonal of the two-dimensional array.

3. The IC device of claim 1, wherein the first dielectric layer is an etch stop layer.

4. The IC device of claim 1, wherein the plurality of dielectric layers further comprises a second dielectric layer, and wherein the first dielectric layer and the second dielectric layer comprise different materials.

5. The IC device of claim 1, wherein, for each of the plurality of first capacitor portions:
the first conductive element comprises a first structure that is vertically oriented in a side view of the IC device;
the dielectric element comprises a second structure coaxial with and internal to the first conductive element; and
the second conductive element comprises a third structure coaxial with and internal to the dielectric element.

6. The IC device of claim 1, further comprising:
a first electrode electrically connected to the first conductive element of each of the first capacitor portions; and
a second electrode electrically connected to the second conductive element of each of the first capacitor portions.

7. The IC device of claim 1, wherein the capacitor structure further comprises:
one or more second capacitor portions, each of the one or more second capacitor portions comprising:
a first conductive element extending through the plurality of dielectric layers, wherein a portion of the first conductive element is shared with a portion of the first conductive element of at least one of the plurality of first capacitor portions;
a dielectric element extending through the plurality of dielectric layers and aligned along the first conductive element; and
a second conductive element extending through the plurality of dielectric layers and aligned along the dielectric element.

8. An integrated circuit (IC) device, comprising:
a substrate;
a plurality of dielectric layers disposed over the substrate;
a capacitor structure comprising a plurality of first capacitor portions, each of the plurality of first capacitor portions comprising:
a first conductive element extending through the plurality of dielectric layers;
a dielectric element extending through the plurality of dielectric layers and aligned along the first conductive element; and
a second conductive element extending through the plurality of dielectric layers and aligned along the dielectric element;
wherein the plurality of first capacitor portions are arranged in a two-dimensional array in a plan view of the IC device;
wherein at least one of the dielectric layers bridges each neighboring pair of the plurality of first capacitor portions aligned along a row or a column of the two-dimensional array; and
wherein the at least one of the dielectric layers comprises a gap between each other neighboring pair of the plurality of first capacitor portions.

9. The IC device of claim 8, wherein the at least one of the dielectric layers comprises an etch stop layer.

10. The IC device of claim 8, wherein each of the plurality of first capacitor portions is oriented vertically through the plurality of dielectric layers.

11. The IC device of claim 8, wherein each of the plurality of first capacitor portions is cylindrical in the plan view of the IC device.

12. A method, comprising:
forming a first electrode over a substrate;
forming a plurality of dielectric layers over the first electrode;
forming a plurality of trenches through the plurality of dielectric layers;
conformally depositing a first conductive structure over the plurality of dielectric layers and into the plurality of trenches;
removing portions of the first conductive structure external to the plurality of trenches;
removing, external to the plurality of trenches, a portion of each of at least one of the plurality of dielectric layers prior to a first dielectric layer of the plurality of dielectric layers;
removing less than an entirety of the first dielectric layer;
removing additional ones of the plurality of dielectric layers via at least one removed portion of the first dielectric layer;
conformally depositing a first conductive material internal and external to the plurality of trenches;
conformally depositing a dielectric material on the first conductive material;
forming a second conductive material on the dielectric material; and
forming a second electrode on the second conductive material.

13. The method of claim 12, wherein each of the plurality of trenches extends to the first electrode.

14. The method of claim 12, wherein the first dielectric layer comprises an etch stop layer.

15. The method of claim 12, wherein the additional ones of the plurality of dielectric layers comprise at least one of silicon oxide or silicon nitride.

16. The method of claim 12, wherein the plurality of trenches are arranged in a two-dimensional array in a plan view.

17. The method of claim 16, wherein, after removing less than the entirety of the first dielectric layer, portions of the first dielectric layer extend between adjacent trenches of each row and each column of the two-dimensional array.

18. The method of claim 12, wherein:
removing, external to the plurality of trenches, a portion of each of at least one of the plurality of dielectric layers comprises removing, external to the plurality of trenches, exposed portions of the plurality of dielectric layers to the first dielectric layer; and
removing less than an entirety of the first dielectric layer comprises:
forming dielectric spacer structures over conductive surfaces internal and external to the plurality of trenches; and
removing an amount of dielectric material from the dielectric spacer structures sufficient to remove portions of the first dielectric layer between neighboring ones of the plurality of trenches separated by at least a first linear distance while leaving intact remaining portions of the first dielectric layer.

19. The method of claim 12, wherein removing portions of the first conductive structure not located in the plurality of trenches, removing, external to the plurality of trenches, a portion of each of at least one of the plurality of dielectric layers prior to a first dielectric layer of the plurality of dielectric layers, and removing less than an entirety of the first dielectric layer are performed using a single etching operation.

20. The method of claim 12, wherein removing additional ones of the plurality of dielectric layers via at least one removed portion of the first dielectric layer is performed using a wet dip removal operation.
